(19) United States
(12) Patent Application Publication
(10) Pub. No.: US 2011/0156759 A1
(43) Pub. Date: Jun. 30, 2011

(54) SAMPLE AND HOLD CIRCUIT AND METHOD FOR CONTROLLING THE SAME

(76) Inventor: Hidemi Noguchi, Tokyo (JP)

(21) Appl. No.: 13/062,261

(22) PCT Filed: Sep. 15, 2009
(86) PCT No.: PCT/JP2009/066095

§ 371 Date: Mar. 4, 2011

(30) Foreign Application Priority Data
Sep. 17, 2008 (JP) 2008-238199

(51) Int. Cl. G11C 27/02

(52) U.S. Cl. 327/94

(57) ABSTRACT

A sample and hold circuit comprises an input stage amplifier circuit for amplifying an input signal and a hold circuit for holding an output signal of the input stage amplifier circuit, with a sampling clock signal as a trigger, is further provided with a bias current switching circuit for switching a bias current of the input stage amplifier circuit to another circuit that is functionally independent of the sample and hold circuit, in a case where the hold circuit is in a hold period, to supply the bias current to the circuit.

### REFERENCE TO RELATED APPLICATION

This application is the National Phase of PCT/JP2009/066095, filed Sep. 15, 2009, which is based upon and claims the benefit of the priority of Japanese patent application No. 2008-238199 filed on Sep. 17, 2008, the disclosure of which is incorporated herein in its entirety by reference thereto.

### TECHNICAL FIELD

The present invention relates to a sample and hold circuit and a method for controlling the circuit, and in particular to a sample and hold circuit of a current switching source-follower type, and a method of controlling the circuit.

### BACKGROUND

In sample and hold circuits used in analog digital converters and the like, which handle high speed signals, a current switching source-follower type sample and hold circuit is frequently used.

FIG. 6 shows a first conventional example of a current switching source-follower type sample and hold circuit (refer to FIG. 8 of Patent Document 2). This sample and hold circuit is configured from an input stage amplifier circuit 1 for amplifying a differential voltage of input signals IN and INB by a prescribed amplification rate, a current switching source-follower type hold circuit 2 for holding an analog output voltage of the input stage amplifier circuit 1, and an output buffer 3 for buffering output of the hold circuit 2.

The input stage amplifier circuit 1 is provided with MOS transistors Tr1 and Tr2, and resistor elements R1 to R4. The MOS transistor Tr1 has a drain connected to a power supply VDD via the resistor element R1, a source connected to a power supply I1 via the resistor element R3, and a gate that is given the input signal IN. The MOS transistor Tr2 has a drain connected to the power supply VDD via the resistor element R2, a source connected to the power supply I1 via the resistor element R4, and a gate that is given the input signal INB of a reverse phase to the input signal IN. This type of input stage amplifier circuit 1 is configured as an input stage differential amplifier circuit, and amplifies a differential voltage of the input signals IN and INB by a prescribed amplification rate, to be supplied to the hold circuit 2 as an output signal PREOUT from the drain of the MOS transistor Tr2.

The hold circuit 2 is provided with MOS transistors Tr3 to Tr5, a current source 12, and a capacitor CH for holding voltage. The MOS transistor Tr3 has a drain connected to the power supply VDD, a source is connected to one end of the capacitor CH and a drain of the MOS transistor Tr5, and a gate is given an output signal PREOUT. The MOS transistor Tr4 has a drain connected to a gate of the MOS transistor Tr3, a source is connected to a current source I2, and a gate is given a sampling clock signal CLKB. The MOS transistor Tr5 has a source connected to the current source I2, and a gate is given a sampling clock signal CLK of reverse phase to the sampling clock signal CLKB. In the capacitor CH, one end is given a hold signal VHOLD and the other end is connected to ground.

The output buffer 3 is provided with a MOS transistor Tr6 and a resistor element R5. The MOS transistor Tr6 has a drain connected to the power supply VDD, an output signal OUT is outputted from a source and the source is connected to ground via the resistor element R5, and a gate is connected to one end of the capacitor CH.

Operation of a sample and hold circuit is described making reference to a timing chart of FIG. 7. First, when the sampling clock signal CLK is at a HIGH level (CLKB is at a LOW level), the input stage amplifier circuit 1 operates simply as a linear amplifier circuit, and outputs a voltage proportional to differential voltage of the input voltages IN and INB as an output signal PREOUT. Furthermore, in the hold circuit 2, since a current from the current source I1 flows to the MOS transistor Tr5 side, the MOS transistor Tr3 operates as simply a source-follower, and while charging the capacitor CH, outputs a voltage in accordance with the output signal PREOUT, as a hold signal VHOLD. The output buffer 3 receives the hold signal VHOLD at high impedance, and, as an output signal OUT, outputs a voltage according to the holding signal VHOLD as an output signal OUT. That is, when the sampling clock signal CLK is at a HIGH level (CLKB is at a LOW level), the sample and hold circuit performs a sample operation as simply an amplifier, and outputs an output signal OUT following an input signal.

On the other hand, when the sampling clock signal CLK is at a LOW level (CLKB is at a HIGH level), with the MOS transistor Tr5 OFF, the current of the current source I2 flows in the resistor element R2 of the input stage amplifier circuit 1 of a front stage via the MOS transistor Tr4. Therefore, a voltage drop of R2×I2 is generated at a connection point with a gate of the MOS transistor Tr3 with respect to the resistor element R2, potential of the output signal PREOUT decreases, and the MOS transistor Tr3 is OFF. (Note that I2>I1 is necessary in order that Tr3 is not ON even if maximum input is applied. With this condition, with regard to the potential of the output signal PREOUT, Tr3 is always in an OFF state according to the voltage drop of R2×I2). In this way, the capacitor CH is separated from the MOS transistor Tr3. However, a charge immediately before the sampling clock signal CLK switches from a HIGH level to a LOW level, is held in the capacitor CH: Therefore, potential of the hold signal VHOLD is held, and a voltage at an instant at which the sampling clock signal changes from a HIGH level to a LOW level, is outputted from the output buffer 3 (hold operation).

In this way, when the sampling clock signal CLK has a HIGH level the conventional sample and hold circuit operates as a simple amplifier, and when the sampling clock signal CLK has a LOW level, operates as a hold circuit for holding the voltage at the instant the sampling clock signal CLK changes from a HIGH level to a LOW level.

However, in the first conventional example, the input stage amplifier circuit 1 operates during the hold period and causes the gate potential (PREOUT) of the MOS transistor Tr3, which is a source follower of the hold circuit 2, to waver. As described above, normally, according to the voltage drop due to the load resistor (R2) of the input stage amplifier circuit 1 and the current of the current source 12 flowing via the MOS transistor Tr4, the potential of the output signal PREOUT is set to be low so that the MOS transistor Tr3 is OFF (I2>I1). As a result, the MOS transistor Tr3 is always in an OFF state. However, since the wavering of the output signal PREOUT leaks into the hold signal VHOLD due to parasitic capacitance between the gate and source of the MOS transistor Tr3, and the hold signal VHOLD is varied, there has been a problem in that the input signal leaks (feeds through) to output.

As a means of solving this feed-through problem, a second conventional example shown in FIG. 8 is disclosed (refer to FIG. 2 of Patent Document 1). In this conventional example, a current bypass circuit 5 is further provided, and by using a bypass transistor TrBp forming the current bypass circuit 5, during a hold period, a bias current (current of a current source I1) of the input stage amplifier circuit 1 is bypassed to the power supply VDD. By the bypass of the bias current (I1), the MOS transistors Tr1 and Tr2 that form an input stage differential pair are OFF, and feed-through is suppressed by arranging such that an input signal is not transmitted to the hold circuit 2 of a subsequent stage.

Furthermore, as another means of suppressing feed-through, a third conventional example shown in FIG. 9 is disclosed (refer to FIG. 2 of Patent Document 2). With regard to the sample and hold circuit of FIG. 6, a circuit in this case is further provided with a bias current switching circuit 4 having MOS transistors Tr7 and Tr8 as a differential pair, and a constant voltage supply circuit 6 having MOS transistors Tr9 and Tr10 as a differential pair. During a hold period, by the bias current switching circuit 4, a bias current (current of the current source I1) of the input stage amplifier circuit 1 is bypassed to the constant voltage supply circuit 6 to which a constant voltage (HIGH/LOW) is applied. By the bypass of the bias current, the feed-through is suppressed by supplying a constant voltage such that the MOS transistor Tr3 is OFF, to the hold circuit 2.
[Patent Document 1]
JP Patent Kokai Publication No. JP-A-9-130168
[Patent Document 2]
JP Patent Kokai Publication No. JP-P2006-157648A

### SUMMARY

It is to be noted that the entire disclosures of the abovementioned patent documents are incorporated herein by reference thereto. The following analysis is given by the present invention.

There has been a problem, however, in a circuit of the second conventional example, in that a bias current (current of a current source I1), which is bypassed to a current source during a hold period, is not involved in a hold operation in a circuit operation, and power is wastefully consumed. Furthermore, in a circuit of the third conventional example, there is a problem in that high frequency characteristics deteriorate due to increasing load on an input stage differential amplifier circuit, and high speed capability is impaired.

In this way, in a conventional means it has been difficult to perform both suppression of feed-through and implementation of low power consumption, without impairing high speed capability.

Therefore, it is an object of the present invention to provide a sample and hold circuit in which feed-through in a hold period is suppressed, and which has good power efficiency by reducing wasteful current consumption without deteriorating high speed capability, and to provide a control method therefor.

A sample and hold circuit according to a first aspect of the present invention is provided with: an input stage amplifier circuit for amplifying an input signal, and a hold circuit for holding an output signal of the input stage amplifier circuit with a sampling clock signal as a trigger, wherein the sample and hold circuit is provided with a bias current switching circuit for switching a bias current of the input stage amplifier circuit to another circuit that is functionally independent of the sample and hold circuit, in a case where the hold circuit is in a hold period, to supply the other circuit.

According to another aspect of the present invention, there is provided a method for controlling a sample and hold circuit that comprises: an input stage amplifier circuit for amplifying an input signal, and a hold circuit for holding an output signal of the input stage amplifier circuit with a sampling clock signal as a trigger, wherein control is performed so as to switch a bias current of the input stage circuit to another circuit that is functionally independent of the sample and hold circuit, in a case where the hold circuit is in a hold period, to supply the other circuit.

According to the present invention, it is possible to improve power efficiency by reducing wasteful current consumption during a hold period.

### BRIEF DESCRIPTION OF THE DRAWINGS

FIG. 1 is a block diagram showing a configuration of a sample and hold circuit according to an embodiment of the present invention.

FIG. 2 is a circuit diagram of a sample and hold circuit according to a first exemplary embodiment of the present invention.

FIG. 3 is a timing chart representing operation of the sample and hold circuit according to the first exemplary embodiment of the present invention.

FIG. 4 is a circuit diagram of a sample and hold circuit according to a second exemplary embodiment of the present invention.

FIG. 5 is a timing chart representing operation of the sample and hold circuit according to the second exemplary embodiment of the present invention.

FIG. 6 is a circuit diagram of a sample and hold circuit of a first conventional example.

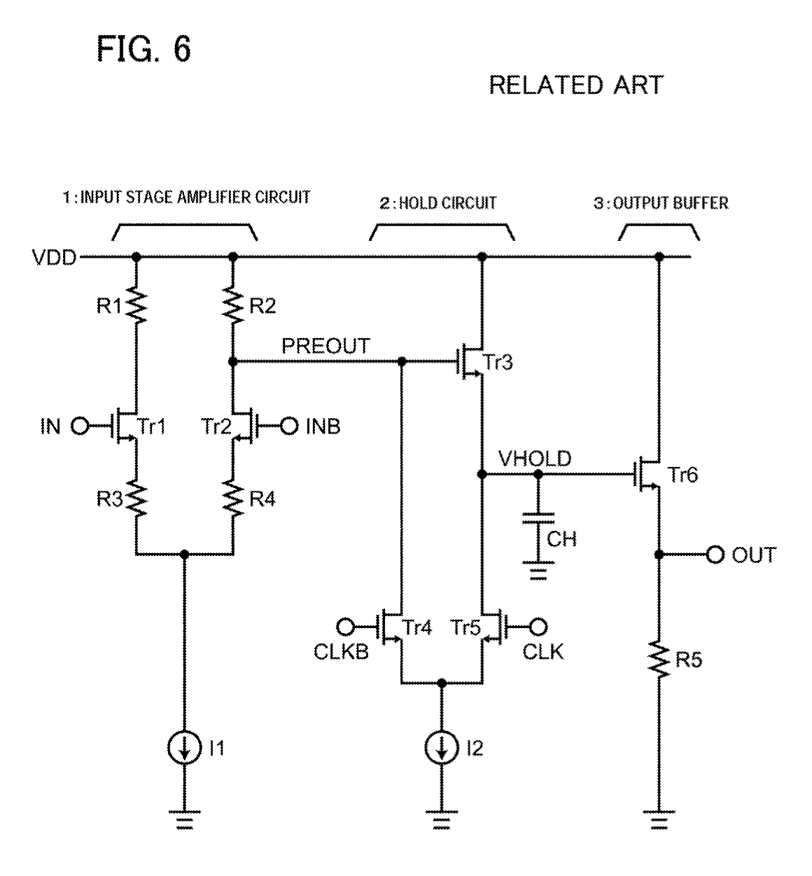

FIG. 7 is a timing chart of the sample and hold circuit of the first conventional example.

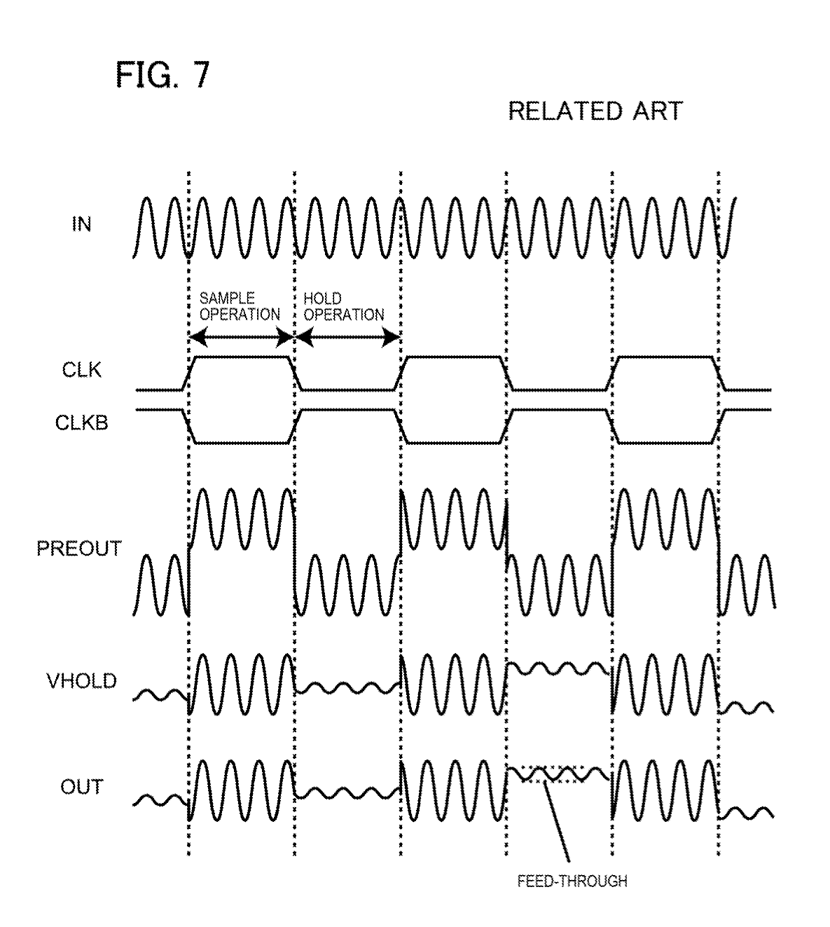

FIG. 8 is a circuit diagram of a sample and hold circuit of a second conventional example.

FIG. 9 is a circuit diagram of a sample and hold circuit of a third conventional example.

### PREFERRED MODES

A sample and hold circuit according to an embodiment of the present invention is provided with: an input stage amplifier circuit for amplifying an input signal, and a hold circuit for holding an output signal of the input stage amplifier circuit with a sampling clock signal as a trigger, wherein the sample and hold circuit is provided with a bias current switching circuit for switching a bias current of the input stage amplifier circuit to another circuit that is functionally independent of the sample and hold circuit, in a case where the hold circuit is in a hold period, to supply the other circuit.

The sample and hold circuit of the present invention may be arranged such that a plurality of the abovementioned sample and hold circuits are provided, with each of the sample and hold circuits being made to perform a time interleaving operation, a single bias current source for an input stage amplifier circuit being provided to be shared as a bias current source for each of the input stage amplifier circuits that perform an interleaving operation, and the bias current switching circuit switches bias current in a time wise manner with respect to the bias current source for an input stage amplifier circuit, to be supplied as a bias current of each of the input stage amplifier circuits.

The sample and hold circuit of the present invention may be arranged such that the input stage amplifier circuit is configured by an input stage differential amplifier circuit by a differential pair, and the bias current switching circuit is configured by a differential pair for bias current switching arranged between the input stage differential amplifier circuit and a bias current source for the input stage differential amplifier circuit.

The sample and hold circuit of the present invention may be arranged such that two systems of the abovementioned sample and hold circuit are provided, wherein when one of the two systems is in a sample period, a time interleaving operation is performed with the other of the two systems in a hold period, one bias current source is provided to be shared by input stage differential amplifier circuits of both of the sample and hold circuits, and a bias current switching circuit, when one of the systems is in a hold period, switches and supplies a current so as to flow a bias current to the other input stage differential amplifier circuit.

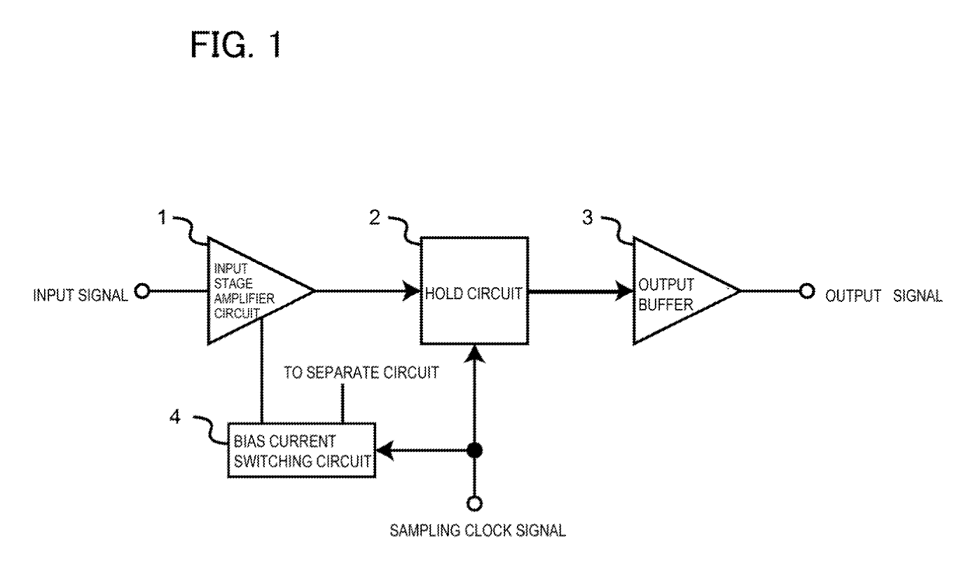

FIG. 1 is a block diagram showing a configuration of the sample and hold circuit according to the embodiment of the present invention. In FIG. 1, the sample and hold circuit is provided with an input stage amplifier circuit 1 for amplifying an input signal by a prescribed amplification rate, a hold circuit 2 for receiving an output of the input stage amplifier circuit 1 and holding an output voltage of the input stage amplifier circuit 1 with a sampling clock signal as a trigger, an output buffer 3 for buffering output of the hold circuit 2, and a bias current switching circuit 4 in which a bias current of the input stage amplifier circuit 1 can be switched to another circuit (referred to below as a separate circuit or separate circuit block) that is functionally independent of this sample and hold circuit. The bias current switching circuit 4 turns the input stage amplifier circuit 1 OFF by switching the bias current of the input stage amplifier circuit 1 to the separate circuit during a hold period in which an output voltage of the input stage amplifier circuit 1 is held, to suppress leaking (feed-through) of the input signal to the output voltage, and also supplies this switched bias current to the separate circuit.

In this way, the sample and hold circuit of the present invention has a configuration for switching a bias current of the input stage amplifier circuit 1 during a hold period to a separate circuit block, using the bias current switching circuit 4. Therefore, since the input stage amplifier circuit 1 is in an OFF state during a hold period and the input signal is not transmitted to the hold circuit 2, it is possible to suppress feed-through. At the same time, by the switched bias current being effectively used in the separate circuit block, it is possible to eliminate wasteful current consumption. Furthermore, in the present sample and hold circuit, since there is no increase in load of the input stage amplifier circuit 1, high speed capability is not impaired.

In addition, an implementation may be made of an interleave type sample and hold circuit where a bias current, which is switched during a hold period, is used as a bias current of an input stage amplifier circuit of another sample and hold circuit that is separately provided, and by performing an interleaving operation by mutually reverse phase sampling clock signals, wasteful current consumption is eliminated and efficiency is good. That is, with respect to the input stage amplifier circuits of two sample and hold circuits that perform a time interleaving operation, by alternately sharing, in a time wise manner, single common bias current sources, it is possible to realize reduced power and elimination of bypass current during a hold period, which flows wastefully in conventional cases.

In a case where a sample and hold circuit has an interleave configuration, the number of sample and hold circuits that perform interleaving is not limited to two. That is, by adjusting a sampling clock signal duty ratio, it is possible to share a single input stage bias current source with three or more sample and hold circuits. Therefore, the larger the number of sample and hold circuits that perform an interleaving operation, the more power efficiency improves, and as a result, it is possible to realize a low power sample and hold circuit.

In this way, according to the sample and hold circuit of the present invention, by switching the bias current of the input stage amplifier circuit 1 to the separate circuit during a hold period in which an output voltage of the input stage amplifier circuit 1 is being held, the input stage amplifier circuit 1 is turned OFF and leaking (feed-through) of the input signal to the output voltage is suppressed, and it is possible to use this switched bias current in a separate circuit.

Furthermore, according to the present invention, a sample and hold circuit is obtained in which a plurality of the sample and hold circuits are lined up, and sampling frequency is improved by making each of them perform a time interleaving operation, a single bias current source is shared by each of the input stage amplifier circuits, and the bias current is switched in a time wise manner to be used as a bias current of each of the input stage amplifier circuits.

A description is given below concerning details of the circuits according to exemplary embodiments.

### First Exemplary Embodiment

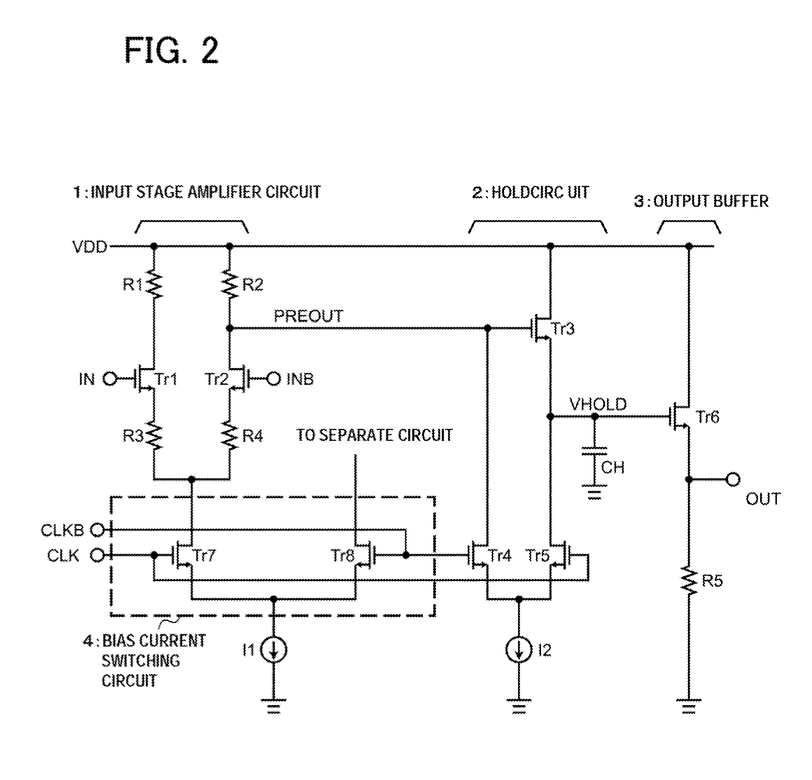

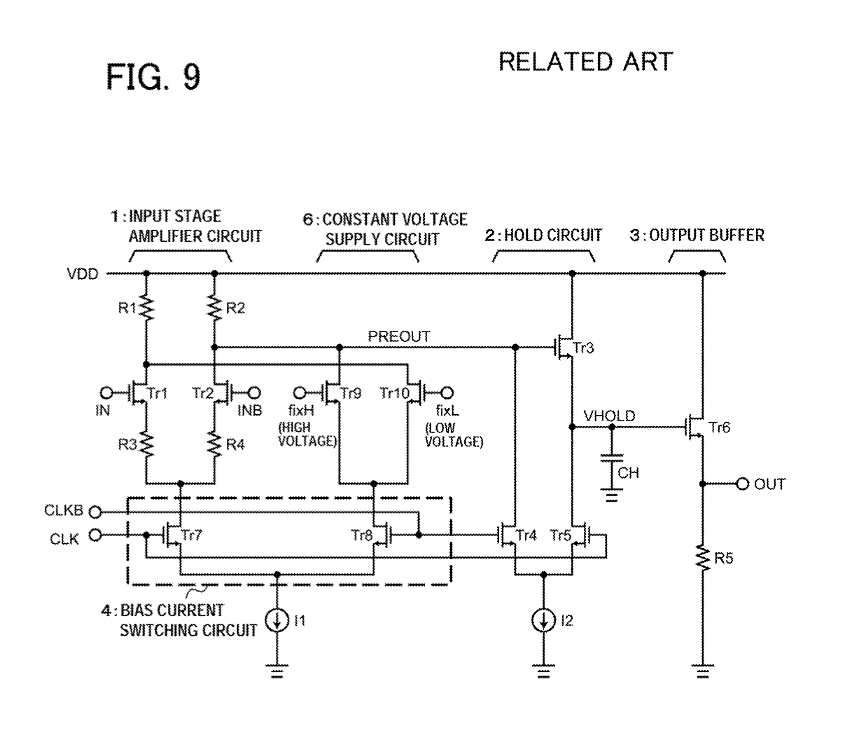

FIG. 2 is a circuit diagram of a sample and hold circuit according to a first exemplary embodiment of the present invention. In FIG. 2, reference symbols the same as FIG. 9 represent the same items, and descriptions thereof are omitted. The sample and hold circuit according to the first exemplary embodiment is configured such that, during a hold period, a bias current (current of a current source I1) of an input stage amplifier circuit 1 is supplied to a separate circuit, by a bias current switching circuit 4.

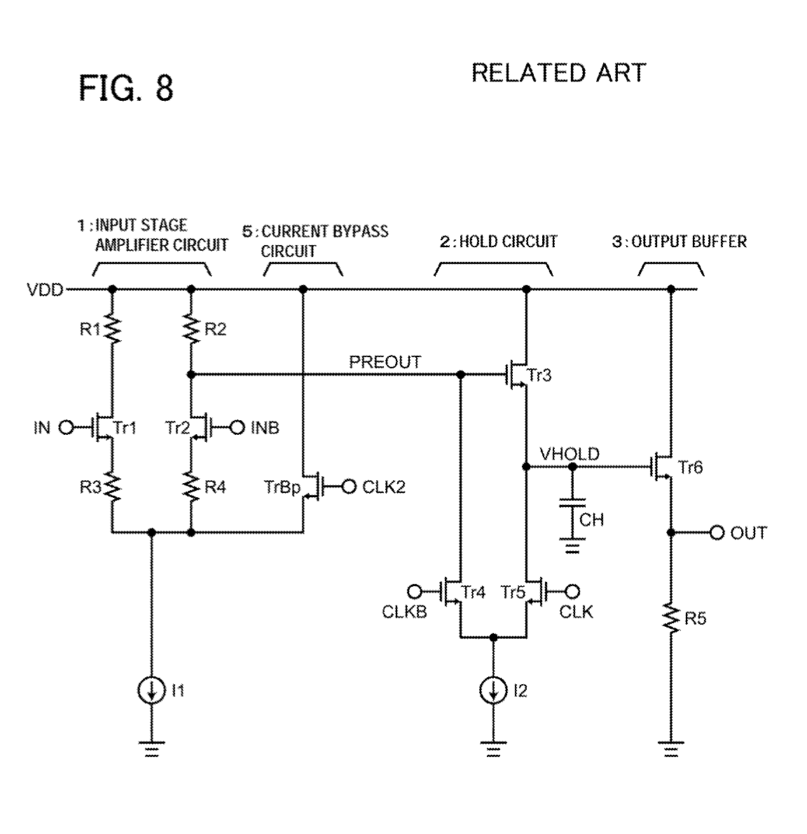

A difference from a second conventional example shown in FIG. 8 is the point that in the conventional example a bypass transistor TrBp connected in parallel to an input stage differential pair Tr1 and Tr2 is used in order that a bias current of an input stage differential amplifier circuit is bypassed, whereas in the present invention, a current switching differential pair by Tr7 and Tr8 is used. Furthermore, a difference from a third conventional example shown in FIG. 9 is the point that a differential pair (Tr9 and Tr10) for giving a constant input voltage, which is necessary in the conventional example, is eliminated, and a switched bias current is bypassed as a bias current of another circuit block, as it is.

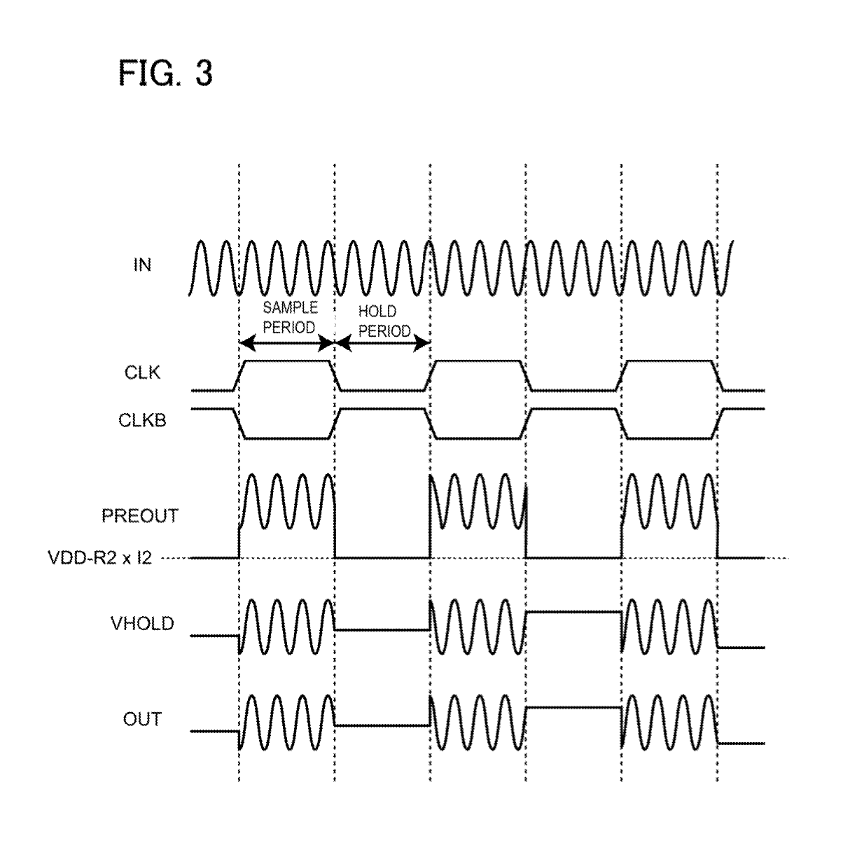

Next, operation of the sample and hold circuit of the present exemplary embodiment is described using a timing chart shown in FIG. 3. When a sampling clock signal CLK is at a HIGH level, a bias current (current of a source current I1) flows to a Tr7 side. Therefore, the input stage amplifier circuit 1 is ON and operates as a differential amplifier circuit. A differential voltage of input signals IN and INB is amplified by a prescribed amplification rate, and an output signal PREOUT is transmitted to a hold circuit 2 of a subsequent stage.

Furthermore, with regard to the hold circuit 2, since a current of a current source 12 flows to the Tr5 side, Tr3 operates as a source follower, receives the output signal PREOUT, and charges a capacitor CHOLD in addition to outputting a hold signal VOLD in response to the output signal PREOUT. An output buffer 3 operates as a buffer of the source follower, the hold signal VHOLD that is the output voltage of the hold circuit 2 is received, and is received at a high impedance and buffered, and an output signal OUT is outputted.

In this way, when the sampling clock CLK is at a HIGH level, operation is in sampling mode, and a voltage in response to an input signal is outputted as the output signal OUT.

On the other hand, when the sampling clock signal CLK is at a LOW level, the sample and hold circuit of the present exemplary embodiment operates in a hold mode, and a voltage at an instant at which the sampling clock signal CLK changes from a HIGH level to a LOW level is held. That is, Tr5 turns OFF at the instant at which the sampling clock signal CLK changes from a HIGH level to a LOW level, and a drive current of Tr3, which forms a source follower, is cut. On the other hand, since Tr4 is ON, a current of the current source 12 flows through Tr4 via a resistor element R2, which is a load of Tr2 in the input stage amplifier circuit 1, and a voltage drop of R2×I2 is generated in the resistor element R2. A potential (gate potential of Tr3) of an output signal PREOUT, which is an output of the input stage amplifier circuit 1 according to the voltage drop, drops, T3 turns OFF, and a capacitor CH for holding voltage is separated from Tr3. At this time, since stored charge is held in the capacitor CH, when the sampling clock signal CLK is at a LOW level, a voltage at the instant the sampling clock signal CLK switches from a HIGH level to a LOW level, is held.

Furthermore, with regard to the differential pair (Tr7 and Tr8) that form the bias current switching circuit 4 at this time, since the Tr8 side is ON, a bias current is not supplied and the input stage amplifier 1 is OFF, and the bias current (current of the current source I1) is bypassed to another circuit via Tr8. Therefore, in a hold period the input stage amplifier circuit 1 has a structure in which, since it is turned OFF, the input signal does not leak to a hold stage, and feed-through is suppressed. It is to be noted that, by there being no bias current of the input stage amplifier circuit 1 at this time, gate potential of Tr3 increases. However, similar to the second conventional example, if a relationship of I2>I1 is held, the transistor Tr3 of the hold circuit 2 does not turn ON, by a voltage drop of R2×I2.

In this way, according to the sample and hold circuit of the present exemplary embodiment, it is possible to raise power efficiency by effectively using the switched bias current in another circuit, while suppressing feed-through by having the input stage amplifier circuit 1 OFF by switching the bias current of the input stage amplifier circuit 1 during a hold period, and lower power can be realized. Furthermore, comparing with the third conventional example, since a load of the input stage amplifier circuit 1 does not increase, a decrease in operation speed is not brought about.

In the sample and hold circuit of the present exemplary embodiment as above, an example of a sample and hold circuit according to MOSFETs is shown, but application is also possible to a case of similar circuits with bipolar transistors.

### Second Exemplary Embodiment

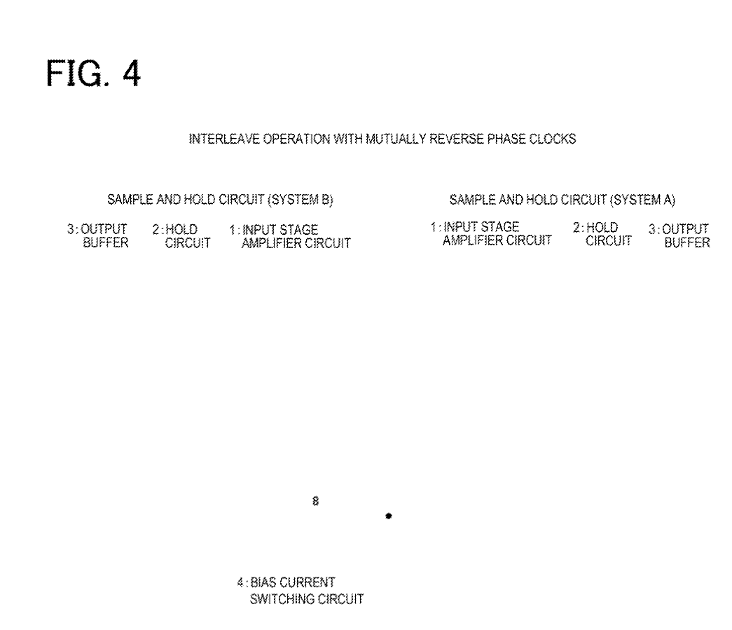

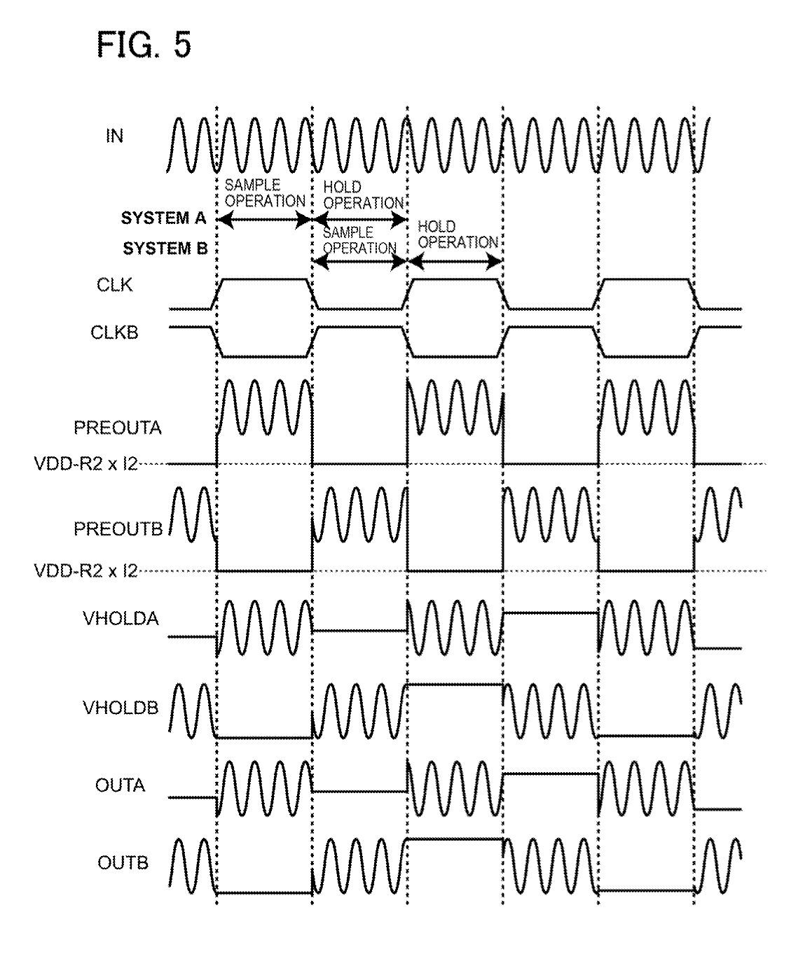

FIG. 4 is a circuit diagram of a sample and hold circuit according to a second exemplary embodiment of the present invention. Furthermore, a timing chart thereof is shown in FIG. 5. With regard to the sample and hold circuit of the present exemplary embodiment, two systems, system A and system B of a sample and hold circuit shown in the first exemplary embodiment are provided, and a time interleaving operation is performed by sampling clock signals having a phase relationship of mutually reversed phases. Furthermore, a configuration is such that a single shared current source I1 for a bias current is shared as a bias current source of input stage amplifier circuits 1 of the two sample and hold circuits, and operation is performed by switching in a time-wise manner (temporally) by a bias current switching circuit 4. That is, the configuration is such that when system A is in a sample mode, system B is in a hold mode, and when system A is in a hold mode, system B is in a sample mode, and interleaving operations are alternately performed; and furthermore, while system A is in a hold mode the shared current source I1 is used as a bias current of the input stage amplifier circuit 1 of system B, and while system B is in a hold mode the shared current source I1 is used as a bias current of the input stage amplifier circuit 1 of system A.

According to this type of sample and hold circuit, it is possible to effectively use a bias current in order to suppress feed-through, which is conventionally wastefully consumed, in another sample and hold circuit that performs an interleave operation by a sampling clock signal of a reverse phase. Therefore, as a result of raising power efficiency, it is possible to realize a low power time interleave type of sample and hold circuit.

Furthermore, in the abovementioned description, an example was described in which two sample and hold circuits perform time interleave operations. However, there is no limitation to this, and it is also possible for three or more sample and hold circuits to perform a time interleave operation. In this case, by changing duty ratio of sampling clock signals CLK and CLKB in accordance with the number of sample and hold circuits, sharing of bias current is possible. Therefore, the more the number of interleaving operations is increased, the higher the power efficiency that can be realized.

Modifications and adjustments of embodiments and examples are possible within the bounds of the entire disclosure (including the scope of the claims) of the present invention, and also based on fundamental technological concepts thereof. Furthermore, a wide variety of combinations and selections of various disclosed elements are possible within the scope of the claims of the present invention. That is, the present invention clearly includes every type of transformation and modification that a person skilled in the art can realize according to the entire disclosure including the scope of the claims and to technological concepts thereof.

### EXPLANATION OF SYMBOLS

1 input stage amplifier circuit
2 hold circuit
3 output buffer
4 bias current switching circuit
CH capacitor
CLK, CLKB sampling clock signals
I1, I2 current sources
IN, INB input signals
OUT, PREOUT output signals
R1, to R5 resistor elements
Tr1 to Tr8 MOS transistors
VHOLD hold signal
VDD power supply

What is claimed is:

1. A sample and hold circuit, comprising:
an input stage amplifier circuit for amplifying an input signal;
a hold circuit for holding an output signal of said input stage amplifier circuit with a sampling clock signal as a trigger; and
a bias current switching circuit for switching a bias current of said input stage amplifier circuit to another circuit that is functionally independent of said sample and hold circuit, in a case where said hold circuit is in a hold period, to supply said circuit.

2. The sample and hold circuit according to claim 1, wherein
a plurality of said sample and hold circuit are provided;
each of said sample and hold circuits is made to perform a time interleaving operation, and a single bias current source for an input stage amplifier circuit is provided to be shared as a bias current source for each of said input stage amplifier circuits that perform an interleaving operation; and
said bias current switching circuit switches a bias current of said bias current source for an input stage amplifier circuit in a time wise manner, to supply said bias current as a bias current of each of said input stage amplifier circuits.

3. The sample and hold circuit according to claim 1, wherein
said input stage amplifier circuit is configured by an input stage differential amplifier circuit by a differential pair, and
said bias current switching circuit is configured by a differential pair for bias current switching arranged between said input stage differential amplifier circuit and a bias current source for said input stage differential amplifier circuit.

4. The sample and hold circuit according to claim 3, herein
two systems of said sample and hold circuit are provided,
when one of said two systems is in a sample period, a time interleaving operation is performed with another of said two systems in a hold period, and one bias current source is provided to be shared by input stage differential amplifier circuits of both of said sample and hold circuits, and
said bias current switching circuit switches and supplies a current so as to flow a bias current to another input stage differential amplifier circuit, when one system is in a hold period.

5. A method for controlling a sample and hold circuit that comprises an input stage amplifier circuit for amplifying an input signal, and a hold circuit for holding an output signal of said input stage amplifier circuit with a sampling clock signal as a trigger,
said method comprising:
performing control so as to switch a bias current of said input stage amplifier circuit to an other circuit that is functionally independent of said sample and hold circuit, in a case where said hold circuit is in a hold period, to supply said other circuit.
